(19) United States
(12) Patent Application Publication
(10) Pub. No.: US 2024/0355916 A1
(43) Pub. Date: Oct. 24, 2024

(54) GAN-BASED HEMT DEVICE, DEVICE EPITAXIAL STRUCTURE, AND PREPARATION METHOD THEREOF

(71) Applicant: Genettice (Qingdao) Semiconductor Materials Co., Ltd., Qingdao (CN)

(72) Inventors: Wang MA, Qingdao (CN); Long CHEN, Qingdao (CN); Jingyun CHENG, Qingdao (CN); Zuyao CHEN, Qingdao (CN); Hongchao WANG, Qingdao (CN); Li YUAN, Qingdao (CN)

(73) Assignee: Genettice (Qingdao) Semiconductor Materials Co., Ltd., Qingdao (CN)

(21) Appl. No.: 18/686,447

(22) PCT Filed: Apr. 26, 2022
(86) PCT No.: PCT/CN2022/089131

§ 371 Date: Feb. 26, 2024

(30) Foreign Application Priority Data
Aug. 27, 2021 (CN) 2021109957032

(51) Int. Cl. H01L 29/778; H01L 29/15; H01L 29/20; H01L 29/66

(52) U.S. Cl. CPC H01L 29/778; H01L 29/155; H01L 29/2003; H01L 29/66462

(57) ABSTRACT

The epitaxial structure sequentially includes from bottom to top a C-doped c-GaN high-resistance layer, a diffusion blocking layer, an intrinsic u-GaN channel layer, and an AlGaN barrier layer that are formed on a substrate. The diffusion blocking layer is a laminate structure or a superlattice structure; where the laminate structure comprises at least two layers selected from a group consisting of at least one Si₃N₄ layer, at least one AlN layer, and at least one GaN layer, and the laminate structure comprises at least one Si₃N₄ layer and also comprises at least one AlN layer or at least one GaN layer; where the superlattice structure is formed by periodically alternating laminate structures. The Si₃N₄ layer can block C atoms in the C-doped c-GaN high-resistance layer from diffusing into the intrinsic u-GaN channel layer. The AlN layer and the GaN layer provide growth transition for the diffusion blocking layer.

### FIELD OF THE INVENTION

The present disclosure relates to the field of semiconductor manufacturing technologies, and in particular, to a GaN-based HEMT device, a device epitaxial structure, and a preparation method thereof.

### BACKGROUND OF THE INVENTION

Wide-bandgap semiconductors using III group nitrides, represented by gallium nitride (GaN), have excellent physical characteristics such as large bandgap width, high electron saturation drift velocity, high critical breakdown electric field, high thermal conductivity, good stability, corrosion resistance ability, and radiation resistance ability, and have become the main material system of third-generation semiconductors, following silicon (Si) and germanium (Ge) of first-generation semiconductors and gallium arsenide (GaAs) and indium phosphide (InP) of second-generation semiconductors. Especially, a GaN heterogeneous structure is regarded as an ideal material for developing microwave power devices due to its high-density and high-mobility two-dimensional electron gas. A GaN-based high electron mobility transistor (HEMT) is a heterojunction field-effect transistor, which is considered as a next-generation semiconductor device, is widely applied in military, aerospace, communication technologies, automotive electronics, and switch-mode power supplies, and especially attracts wide attention in high-power and high-frequency application fields.

In the field of power devices, good electrical isolation performance can reduce an off-set leakage, to obtain good channel interruption performance and high breakdown voltage. Therefore, a semi-insulating GaN material is very important in manufacturing a field-effect transistor with a GaN-based heterogeneous structure.

A GaN material has a bandgap width of 3.4 eV at room temperature and is a wide-bandgap semiconductor. At room temperature, densities of conduction band electrons and valence band holes generated from thermal excitation are nearly zero. If the GaN material includes no impurity and has perfect crystal lattices, the GaN material is a high-resistance material, and a high-purity GaN material with perfect crystal lattices is an ideal high-resistance GaN material. However, it is very difficult to obtain the high-purity GaN material with perfect crystal lattices, and in practice unintentionally doped intrinsic GaN is usually of an n-type.

The resistivity of a semiconductor material is inversely proportional to the sum of the product of the conduction band electron concentration multiplied by the electron mobility and the valence band hole concentration multiplied by the hole mobility. Therefore, to obtain high-resistance GaN material, the conduction band electron concentration and valence band hole concentration in GaN need to be reduced, and the electron mobility and the hole mobility need to be reduced. Accordingly, the following two methods are usually used to obtain high-resistance GaN. In the first method, structural defects such as dislocations are intentionally introduced into a GaN material. The structural defects may generate an electron trapping level or acceptor level into the bandgap of GaN, to enable conduction band electrons to be trapped by electron traps or compensated by acceptors, so that high-resistance GaN material can be obtained. A common method is to introduce high-density edge dislocations. In the second method, impurities such as iron (Fe) or carbon (C) atoms are intentionally doped in a GaN material. These impurities may generate an electron trapping level or acceptor level into the bandgap of GaN, to enable conduction band electrons to be trapped by electron traps or compensated by acceptors, so that high-resistance GaN material can be obtained.

However, the high density dislocations introduced by using an intrinsic dislocation technology may reduce the reliability of the AlGaN/GaN HEMT device. In addition, at a high voltage, intrinsic dislocations may trap charges and then result in current collapse. Fe-doped GaN is limited by the strong memory effect of Fe, therefore, the doping range cannot be too wide. In addition, Fe-doped GaN has poor insulation performance, and high Fe doping also causes current collapse. Carbon (C)-doped GaN has better stability and less memory effect, and also has a higher breakdown voltage. Therefore, carbon-doped GaN is selected to obtain the high-resistance GaN material. However, when using a metal organic chemical vapor deposition (MOCVD) method to obtain a specific C doping concentration, it is usually necessary to lower the growth temperature of GaN to implement self-doping, or to use a carbon source such as ethylene (C₂H₄) to implement external doping. No matter which C doping method is used, the crystal quality of the GaN material is not perfect to some extent due to the introduction of high-concentration C impurities, in addition, the defects caused by C doping can also reduce device reliability and cause current collapse.

To mitigate as much as possible the foregoing problems of reduced device reliability and current collapse caused by C doping, a method commonly used in the industry at present is to further epitaxially grow an intrinsic u-GaN channel layer on a C-doped c-GaN high-resistance layer, to form an AlGaN barrier layer/u-GaN channel layer/c-GaN high-resistance layer structure, so that a two-dimensional electron gas with better performance is formed at an interface of AlGaN barrier layer/u-GaN channel layer. In this way, high electrical isolation performance is achieved through c-GaN, and intrinsic u-GaN is used as a conductive channel to avoid a series of problems caused by C doping.

However, even if the foregoing measures are taken, the problems of reduced device reliability and current collapse cannot be completely solved due to the easy diffusion of C atoms in the C-doped c-GaN high-resistance layer to the intrinsic u-GaN channel layer, which results from a large concentration difference between the C-doped c-GaN high-resistance layer and the intrinsic u-GaN channel layer.

### SUMMARY OF THE INVENTION

The present invention provides a GaN-based HEMT device, a device epitaxial structure, and a preparation method thereof, which solve problems such as reliability degradation and possible current collapse of a GaN-based HEMT device caused by easy diffusion of C atoms in the C-doped c-GaN high-resistance layer to the intrinsic u-GaN channel layer in the existing GaN-based HEMT device epitaxial structure.

The present invention provides a GaN-based HEMT device epitaxial structure, sequentially comprising from bottom to top a C-doped c-GaN high-resistance layer, a diffusion blocking layer, an intrinsic u-GaN channel layer, and an AlGaN barrier layer that are formed on a substrate;
where the diffusion blocking layer is a laminate structure or a superlattice structure. The laminate structure comprises at least two layers selected from a group consisting of at least one Si₃N₄ layer, at least one AlN layer, and at least one GaN layer, and the laminate structure comprises at least one Si₃N₄ layer and also comprises at least one AlN layer or at least one GaN layer. The superlattice structure is formed by periodically alternating laminate structures.

Optionally, a buffer layer is formed between the substrate and the C-doped c-GaN high-resistance layer.

Optionally, the number of the laminate structures in the superlattice structure ranges from 2 to 100.

Optionally, a doping concentration of the C-doped c-GaN high-resistance layer ranges from 1E+18 cm⁻³ to 3E+19 cm⁻³.

Optionally, a thickness of the Si₃N₄ layer ranges from 0.1 nm to 30 nm, a thickness of the AlN layer ranges from 0.1 nm to 100 nm, and a thickness of the GaN layer ranges from 0.1 nm to 4000 nm.

Optionally, a GaN cap layer and/or a p-GaN cap layer is formed on the AlGaN barrier layer of the epitaxial structure.

The present invention further provides a GaN-based HEMT device. The HEMT device is prepared based on the foregoing GaN-based HEMT device epitaxial structure.

The present invention further provides a preparation method for a GaN-based HEMT device epitaxial structure. The preparation method comprises:
providing a substrate; and
sequentially depositing a C-doped c-GaN high-resistance layer, a diffusion blocking layer, an intrinsic u-GaN channel layer, and an AlGaN barrier layer on the substrate by using a MOCVD process, where the diffusion blocking layer is a laminate structure or a superlattice structure. The laminate structure comprises at least two layers selected from a group consisting of at least one Si₃N₄ layer, at least one AlN layer, and at least one GaN layer, and the laminate structure comprises at least one Si₃N₄ layer and also comprises at least one AlN layer or at least one GaN layer. The superlattice structure is formed by periodically alternating laminate structures.

Optionally, parameters for depositing the diffusion blocking layer are as follows: a growth temperature ranges from 900° C. to 1200° C., a growth pressure ranges from 20 mbar to 500 mbar, a gas source comprises ammonia, a flow rate of ammonia ranges from 1 sccm to 100000 sccm, and a growth atmosphere is nitrogen, hydrogen, or a mixture of them.

The present invention further provides a preparation method for a GaN-based HEMT device. The preparation method for the GaN-based HEMT device comprises the foregoing preparation method for the GaN-based HEMT device epitaxial structure.

As discussed above, the GaN-based HEMT device, the device epitaxial structure, and the preparation method thereof are provided in the present invention, where the diffusion blocking layer is disposed between the C-doped c-GaN high-resistance layer and the intrinsic u-GaN channel layer of the GaN-based HEMT device epitaxial structure. The Si₃N₄ layer in the diffusion blocking layer has excellent shielding capability, and can effectively shield against diffusion of impurity atoms. Therefore, C atoms in the C-doped c-GaN high-resistance layer can be effectively blocked from diffusing into the intrinsic u-GaN channel layer. On the basis of the Si₃N₄ layer, the AlN layer and the GaN layer are further arranged, where the AlN layer has a high infiltration ability, and the GaN layer is made of a material homogeneous with that of the high-resistance layer and the channel layer. Both of them can provide growth transition for the growth of the diffusion blocking layer, so that the diffusion blocking layer can realize better crystal growth quality while achieving shielding effect, thus achieving optimal doping and blocking effect and device performance.

### BRIEF DESCRIPTION OF DRAWINGS

FIG. 1 is a schematic structural diagram of a GaN-based HEMT device epitaxial structure according to the present invention.

FIG. 2 is a schematic structural diagram of a laminate structure in the GaN-based HEMT device epitaxial structure according to Experimental example 1 of the present invention.

FIG. 3 is a schematic structural diagram of the GaN-based HEMT device epitaxial structure according to Experimental example 1 of the present invention.

FIG. 4 is a schematic structural diagram of a laminate structure in a GaN-based HEMT device epitaxial structure according to Experimental example 2 of the present invention.

FIG. 5 is a schematic structural diagram of the GaN-based HEMT device epitaxial structure according to Experimental example 2 of the present invention.

### REFERENCE NUMERALS

10 Substrate
11 C-doped c-GaN high-resistance layer
12 Diffusion blocking layer
120 Laminate structure
121 Si₃N₄ layer
122 AlN layer
123 GaN layer
124 Superlattice structure
13 Intrinsic u-GaN channel layer
14 AlGaN barrier layer
15 Buffer layer

### DETAILED DESCRIPTION OF THE INVENTION

The following describes the embodiments of the present invention through specific examples. A person skilled in the art can easily understand other advantages and effects of the present invention from the content disclosed in this specification. The present invention may be implemented or applied through other different specific embodiments. Various details in this specification may also be modified or changed based on different viewpoints and applications without departing from the spirit of the present invention.

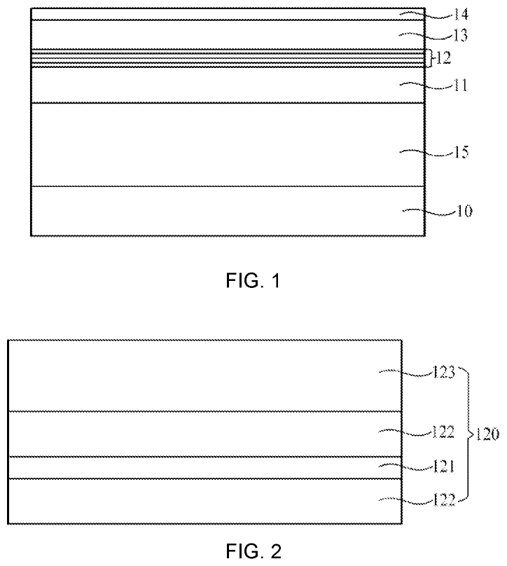

When referring to FIG. 1 to FIG. 5, it should be noted that the drawings provided in this embodiment only exemplarily illustrate the basic idea of the present invention. Therefore, only the components related to the present invention are shown in the drawings, and are not drawn according to the number, shape, and size of the components during actual implementation. The type, number, and proportion of the components may be changed according to an actual requirement, and the layout of the components may be more complicated.

### Embodiment 1

As shown in FIG. 1, this embodiment provides a GaN-based HEMT device epitaxial structure. The epitaxial structure sequentially comprises from bottom to top a C-doped c-GaN high-resistance layer 11, a diffusion blocking layer 12, an intrinsic u-GaN channel layer 13, and an AlGaN barrier layer 14 that are formed on a substrate 10.

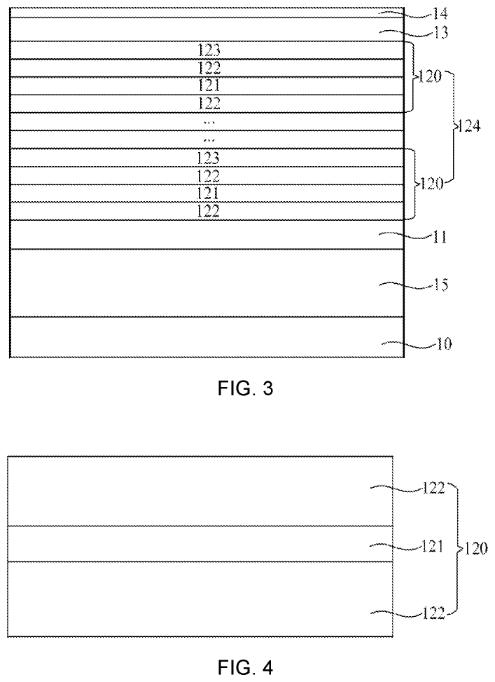

As shown in FIG. 1 and FIG. 2, the diffusion blocking layer 12 is a laminate structure 120 formed by at least two layers selected from a group consisting of at least one Si₃N₄ layer 121, at least one AlN layer 122, and at least one GaN layer 123, and the laminate structure 120 comprises at least one Si₃N₄ layer 121 and also comprises at least one AlN layer 122 or at least one GaN layer 123. As shown in FIG. 3, the diffusion blocking layer 12 is a superlattice structure 124 formed by periodically alternating laminate structures 120.

In this embodiment, the diffusion blocking layer 12 is disposed between the C-doped c-GaN high-resistance layer 11 and the intrinsic u-GaN channel layer 13 of the GaN-based HEMT device epitaxial structure. The Si₃N₄ layer 121 in the diffusion blocking layer 12 has excellent shielding capability, and can effectively shield against diffusion of impurity atoms. Therefore, C atoms in the C-doped c-GaN high-resistance layer 11 can be effectively blocked from diffusing into the intrinsic u-GaN channel layer 13. On the basis of the Si₃N₄ layer 121, the AlN layer 122 and the GaN layer 123 are further arranged, where the AlN layer 122 has a high infiltration ability, and the GaN layer 123 is made of a material homogeneous with that of the high-resistance layer and the channel layer. Both of them can provide growth transition for the growth of the diffusion blocking layer 12, so that the diffusion blocking layer 12 can realize better crystal growth quality while achieving the shielding effect, thus achieving optimal doping and blocking effect and device performance.

As an example shown in FIG. 1, a buffer layer 15 is formed between the substrate 10 and the C-doped c-GaN high-resistance layer 11. The buffer layer 15 is used for mitigating lattice mismatch and thermal mismatch between the substrate 10 and the C-doped c-GaN high-resistance layer 11, to improve the growth quality of the epitaxial structure. The Si₃N₄ layer 121 has an inert insulating material characteristic, so that electricity leakage of the buffer layer 15 can be alleviated to some extent, thus improving the voltage resistance ability of the device. In addition, an epitaxial growth mode of Si₃N₄ on the surfaces of the GaN layer and the AlN layer is preferably transverse epitaxial growth, that is, Si₃N₄ grows preferably along a two-dimensional direction parallel to the interfaces of the GaN layer and the AlN layer. This transverse epitaxial growth mode can reduce propagation of penetrating dislocations to some extent, to improve crystal growth quality and reduce electricity leakage in the buffer layer, thereby improving a voltage-resistance characteristic of the device.

In an example, a doping concentration of the C-doped c-GaN high-resistance layer 11 may be set according to an actual resistance characteristic requirement. Preferably, the diffusion blocking layer 12 in this embodiment can make the doping concentration of the C-doped c-GaN high-resistance layer 11 range from 1E+18 cm⁻³ to 3E+19 cm⁻³ on the basis of ensuring device performance.

In an example, based on the formed structure of the GaN-based HEMT device, a GaN cap layer may further be arranged on the AlGaN barrier layer 14 of the epitaxial structure, to form a depletion-type GaN-based HEMT device. Alternatively, a p-GaN cap layer may be arranged on the AlGaN barrier layer 14 of the epitaxial structure, to form an enhanced GaN-based HEMT device. Alternatively, both the GaN cap layer and the p-GaN cap layer may be arranged on the AlGaN barrier layer 14 of the epitaxial structure, to form an enhanced GaN-based HEMT device, where the GaN cap layer is used for protecting the AlGaN barrier layer 14.

In an example, the laminate structure 120 comprises at least two layers selected from a group consisting of at least one Si₃N₄ layer 121, at least one AlN layer 122, and at least one GaN layer 123, and comprises at least one Si₃N₄ layer 121 and also comprises at least one AlN layer 122 or at least one GaN layer 123. It may be understood that the laminate structure 120 comprises no less than two layers with one Si₃N₄ layer 121 as a necessity and one AlN layer 122 or GaN layer 123 as an addition. For example, the laminate structure 120 may consist of one AlN layer and one Si₃N₄ layer (AlN layer/Si₃N₄ layer), or one GaN layer and one Si₃N₄ layer (GaN layer/Si₃N₄ layer), or one AlN layer, one Si₃N₄ layer, and one GaN layer (AlN layer/Si₃N₄ layer/GaN layer), in which there are no repetitive layers. Alternatively, the laminate structure 120 may consist of one AlN layer, one Si₃N₄ layer, and one AlN layer (AlN layer/Si₃N₄ layer/AlN layer), or one GaN layer, one Si₃N₄ layer, and one GaN layer (GaN layer/Si₃N₄ layer/GaN layer), or one AlN layer, one Si₃N₄ layer, one AlN layer, and one GaN layer (AlN layer/Si₃N₄ layer/AlN layer/GaN layer), in which there are repetitive layers (the repetitive layers herein refer to those made of the same material, and the thickness of these repetitive layers is not limited to be the same). The stacking order of layers in the laminate structure 120 is not limited. For example, the laminate structure may consist of one AlN layer, one Si₃N₄ layer, and one GaN layer (AlN layer/Si₃N₄ layer/GaN layer), or one Si₃N₄ layer, one AlN layer, and one GaN layer (Si₃N₄ layer/AlN layer/GaN layer).

In an example, when the diffusion blocking layer 12 is the superlattice structure 124 formed by periodically alternating laminate structures 120, the number of the laminate structures 120 in the superlattice structure 124 ranges from 2 to 100.

In an example, in the diffusion blocking layer 12, a thickness of the Si₃N₄ layer 121 ranges from 0.1 nm to 30 nm, a thickness of the AlN layer 122 ranges from 0.1 nm to 100 nm, and a thickness of the GaN layer 123 ranges from 0.1 nm to 4000 nm.

The GaN-based HEMT device epitaxial structure in this embodiment is described below with reference to specific experimental examples.

### Experimental Example 1

As shown in FIG. 2 and FIG. 3, this experimental example provides a GaN-based HEMT device epitaxial structure. The epitaxial structure sequentially comprises from bottom to top the buffer layer 15, the C-doped c-GaN high-resistance layer 11, the diffusion blocking layer 12, the intrinsic u-GaN channel layer 13, and the AlGaN barrier layer 14 that are formed on the substrate 10.

The substrate 10 may be selectively a Si substrate, a C-plane sapphire substrate, a SiC substrate, or a GaN substrate, or may be any other substrate suitable for preparing the GaN-based HEMT device epitaxial structure.

The buffer layer 15 may be an AlN layer, an AlGaN layer, or a GaN layer, or may be a superlattice structure formed by periodically alternating laminates, where the laminate comprises the AlN layer, the AlGaN layer, and the GaN layer.

A doping concentration of the C-doped c-GaN high-resistance layer 11 ranges from 1E+18 cm⁻³ to 3E+19 cm⁻³.

The diffusion blocking layer 12 is a superlattice structure 124, in which the laminate structures 120 are formed by one AlN layer 122, one Si₃N₄ layer 121, one AlN layer 122, and one GaN layer 123 (AlN layer 122/Si₃N₄ layer 121/AlN layer 122/GaN layer 123). In each laminate structure 120, a thickness of the AlN layer 122 is 1 nm, a thickness of the Si₃N₄ layer 121 is 0.8 nm, a thickness of the AlN layer 122 is 1 nm, and a thickness of the GaN layer 123 is 5 nm sequentially. The number of the laminate structures 120 forming the superlattice structure 124 is 3.

The diffusion of C atoms in the C-doped c-GaN high-resistance layer 11 into the intrinsic u-GaN channel layer 13 can be reduced as much as possible, while balancing the crystal quality and the final performance of the device by adjusting the number of the laminate structures 120. In addition, the laminate structure 120 consisting of one AlN layer 122, one Si₃N₄ layer 121, one AlN layer 122, and one GaN layer 123 (AlN layer 122/Si₃N₄ layer 121/AlN layer 122/GaN layer 123), which has a high infiltration ability of the AlN layer and homogeneity of the GaN layer simultaneously, improves the shielding ability and ensures the growth quality of the crystal.

### Experimental Example 2

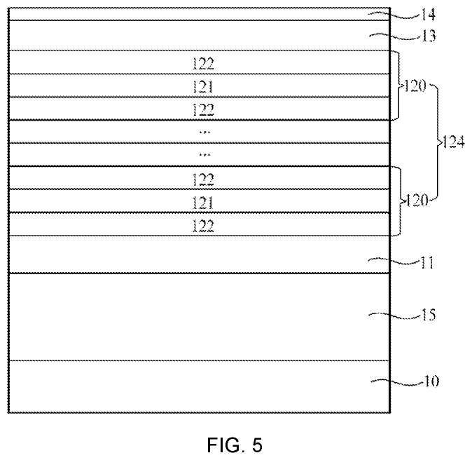

As shown in FIG. 4 and FIG. 5, this experimental example provides a GaN-based HEMT device epitaxial structure. The epitaxial structure sequentially comprises from bottom to top the buffer layer 15, the C-doped c-GaN high-resistance layer 11, the diffusion blocking layer 12, the intrinsic u-GaN channel layer 13, and the AlGaN barrier layer 14 that are formed on the substrate 10.

The substrate 10 may be selectively a Si substrate, a C-plane sapphire substrate, a SiC substrate, or a GaN substrate, or may be any other conventional substrate.

The buffer layer 15 may be an AlN layer, an AlGaN layer, or a GaN layer, or may be a superlattice structure formed by periodically alternating laminates, where the laminate is formed by the AlN layer, the AlGaN layer, and the GaN layer.

A doping concentration of the C-doped c-GaN high-resistance layer 11 ranges from 1E+18 cm⁻³ to 3E+19 cm⁻³.

The diffusion blocking layer 12 is a superlattice structure 124, and the laminate structures 120 are formed by one AlN layer 122, one Si₃N₄ layer 121, and one AlN layer 122 (AlN layer 122/Si₃N₄ layer 121/AlN layer 122). In each laminate structure 120, a thickness of the AlN layer 122 is 0.6 nm, a thickness of the Si₃N₄ layer 121 is 0.4 nm, and a thickness of the AlN layer 122 is 0.6 nm sequentially. The number of the laminate structures 120 forming the superlattice structure 124 is 10.

The diffusion of C atoms in the C-doped c-GaN high-resistance layer 11 into the intrinsic u-GaN channel layer 13 can be reduced as much as possible, while balancing the crystal quality and the final performance of the device by adjusting the number of the laminate structures 120. In addition, the laminate structure 120 consisting of one AlN layer 122, one Si₃N₄ layer 121, and one AlN layer 122 (AlN layer 122/Si₃N₄ layer 121/AlN layer 122), which has a high infiltration ability of the AlN layer, improves the shielding ability and ensures the growth quality of the crystal.

This embodiment further provides a GaN-based HEMT device. The GaN-based HEMT device is prepared based on the GaN-based HEMT device epitaxial structure provided in this embodiment.

### Embodiment 2

This embodiment provides a preparation method for a GaN-based HEMT device epitaxial structure. The preparation method may be used for preparing the GaN-based HEMT device epitaxial structure in the foregoing Embodiment 1. Please refer to Embodiment 1 for the beneficial effect that can be achieved by the preparation method, therefore, details will not be repeated below.

As shown in FIG. 1, the preparation method for the GaN-based HEMT device epitaxial structure comprises:
providing the substrate 10; and
sequentially depositing the C-doped c-GaN high-resistance layer 11, the diffusion blocking layer 12, the intrinsic u-GaN channel layer 13, and the AlGaN barrier layer 14 on the substrate 10 by using a MOCVD process. The diffusion blocking layer 12 is a laminate structure 120 comprising at least two layers selected from a group consisting of at least one Si₃N₄ layer 121, at least one AlN layer 122, and at least one GaN layer 123, and the laminate structure 120 comprises at least one Si₃N₄ layer 121 and also comprises at least one AlN layer 122 or at least one GaN layer 123. Alternatively, as shown in FIG. 3, the diffusion blocking layer 12 is a superlattice structure 124 formed by periodically alternating laminate structures 120.

In an example, the parameters of the MOCVD process for depositing the diffusion blocking layer 12 are as follows: a growth temperature ranges from 900° C. to 1200° C., a growth pressure ranges from 20 mbar to 500 mbar, a gas source comprises ammonia, a flow rate of ammonia ranges from 1 sccm to 100000 sccm, and a growth atmosphere is nitrogen, hydrogen, or a mixture of them.

This embodiment further provides a preparation method for a GaN-based HEMT device. The preparation method comprises the preparation method for the GaN-based HEMT device epitaxial structure provided in this embodiment.

In summary, the GaN-based HEMT device, the device epitaxial structure, and the preparation method thereof are provided in the present invention, where the diffusion blocking layer is disposed between the C-doped c-GaN high-resistance layer and the intrinsic u-GaN channel layer of the GaN-based HEMT device epitaxial structure. The Si₃N₄ layer in the diffusion blocking layer has excellent shielding capability, and can effectively shield against diffusion of impurity atoms. Therefore, C atoms in the C-doped c-GaN high-resistance layer can be effectively blocked from diffusing into the intrinsic u-GaN channel layer. On the basis of the Si₃N₄ layer, the AlN layer and the GaN layer are further arranged, where the AlN layer has a high infiltration ability, and the GaN layer is made of a material homogeneous with that of the high-resistance layer and the channel layer. Both of them can provide growth transition for the growth of the diffusion blocking layer, so that the diffusion blocking layer can realize better crystal growth quality while achieving shielding effect, thus achieving optimal doping and blocking effect and device performance. Therefore, the present invention effectively overcomes various defects in the prior art, and has a high value in industrial use.

The above embodiments only exemplarily illustrate the principles and effects of the present invention, and are not used to limit the present invention. Anyone familiar with the art can modify or change the above embodiments without departing from the spirit and scope of the present invention. Therefore, any equivalent modifications or changes completed by a person of ordinary skill in the art without departing from the spirit and technical concept disclosed in the present invention should still fall within the scope of claims of the present invention.

1. A GaN-based HEMT device epitaxial structure, sequentially comprising from bottom to top a C-doped c-GaN high-resistance layer, a diffusion blocking layer, an intrinsic u-GaN channel layer, and an AlGaN barrier layer that are formed on a substrate;
wherein the diffusion blocking layer is a laminate structure or a superlattice structure;
wherein the laminate structure comprises at least two layers selected from a group consisting of at least one Si₃N₄ layer, at least one AlN layer, and at least one GaN layer, and the laminate structure comprises at least one Si₃N₄ layer and also comprises at least one AlN layer or at least one GaN layer;
wherein the superlattice structure is formed by periodically alternating laminate structures.

2. The GaN-based HEMT device epitaxial structure of claim 1, wherein a buffer layer is formed between the substrate and the C-doped c-GaN high-resistance layer.

3. The GaN-based HEMT device epitaxial structure of claim 1, wherein a number of the laminate structures in the superlattice structure ranges from 2 to 100.

4. The GaN-based HEMT device epitaxial structure of claim 1, wherein a doping concentration of the C-doped c-GaN high-resistance layer ranges from 1E+18 cm⁻³ to 3E+19 cm⁻³.

5. The GaN-based HEMT device epitaxial structure of claim 1, wherein a thickness of the Si₃N₄ layer ranges from 0.1 nm to 30 nm, a thickness of the AlN layer ranges from 0.1 nm to 100 nm, and a thickness of the GaN layer ranges from 0.1 nm to 4000 nm.

6. The GaN-based HEMT device epitaxial structure of claim 1, wherein a GaN cap layer and/or a p-GaN cap layer is formed on the AlGaN barrier layer of the epitaxial structure.

7. A GaN-based HEMT device, wherein the HEMT device is prepared based on the GaN-based HEMT device epitaxial structure of claim 1.

8. A preparation method for a GaN-based HEMT device epitaxial structure, comprising:
providing a substrate; and
sequentially depositing a C-doped c-GaN high-resistance layer, a diffusion blocking layer, an intrinsic u-GaN channel layer, and an AlGaN barrier layer on the substrate by using a MOCVD process,
wherein the diffusion blocking layer is a laminate structure or a superlattice structure;
wherein the laminate structure comprises at least two layers selected from a group consisting of at least one Si₃N₄ layer, at least one AlN layer, and at least one GaN layer, and the laminate structure comprises at least one Si₃N₄ layer and also comprises at least one AlN layer or at least one GaN layer;
wherein the superlattice structure is formed by periodically alternating laminate structures.

9. The preparation method for the GaN-based HEMT device epitaxial structure of claim 8, wherein parameters for depositing the diffusion blocking layer are as follows: a growth temperature ranges from 900° C. to 1200° C., a growth pressure ranges from 20 mbar to 500 mbar, a gas source comprises ammonia, a flow rate of ammonia ranges from 1 sccm to 100000 sccm, and a growth atmosphere is nitrogen, hydrogen, or a mixture of them.

10. A preparation method for a GaN-based HEMT device, wherein the preparation method for the GaN-based HEMT device comprises the preparation method for the GaN-based HEMT device epitaxial structure of claim 8.
